(19) United States
(12) Patent Application Publication
(10) Pub. No.: US 2026/0154466 A1
(43) Pub. Date: Jun. 4, 2026

(54) METHOD AND APPARATUS FOR DESIGNING POWERTRAIN SYSTEM ARCHITECTURE FOR A MOBILITY APPARATUS BASED ON ALLOWABLE FAILURE RATE OF SYSTEM AND RELIABILITY

(71) Applicants: HYUNDAI MOTOR COMPANY, SEOUL (KR); KIA CORPORATION, SEOUL (KR); Konkuk University Industrial Cooperation Corp, Seoul (KR)

(72) Inventors: Jeong A Yang, Hwaseong-si (KR); Tae Yun Choi, Hwaseong-si (KR); Woo Suk Jung, Hwaseong-si (KR); Keun Seok Lee, Hwaseong-si (KR); Eu Gene Hwang, Hwaseong-si (KR); Jae Woo Lee, Seoul (KR); Maxim Tyan, Seoul (KR); Win Thu Zin, Seoul (KR); Dong Oh Kwag, Seoul (KR)

(73) Assignees: HYUNDAI MOTOR COMPANY, SEOUL (KR); KIA CORPORATION, SEOUL (KR); Konkuk University Industrial Cooperation Corp, Seoul (KR)

(21) Appl. No.: 19/397,758

(22) Filed: Nov. 21, 2025

(30) Foreign Application Priority Data
Nov. 29, 2024 (KR) 10-2024-0174694

(51) Int. Cl. G06F 30/15

(52) U.S. Cl. CPC G06F 30/15

(57) ABSTRACT

Disclosed herein is a method and apparatus for designing a powertrain system architecture for a mobility apparatus based on allowable failure rate of system and reliability. The method includes generating an available power rate under failure of a system based on a failure scenario according to a failure of components in the system architecture, generating a system reliability according to the failure scenario based on a failure rate of the component and a connection combination between the components of the system architecture, determining severity data of the system related to the available power rate under failure, based on risk level data indicating a correlation between a risk level and a power reduction rate of the system according to the available power rate under failure, and determining whether to adopt the system architecture based on an allowable failure rate of the system corresponding to the severity data and the system reliability.

### CROSS-REFERENCE TO RELATED APPLICATION(S)

This application claims priority to and the benefit of Korean Patent Application No. 10-2024-0174694, filed on Nov. 29, 2024, the disclosure of which is incorporated herein by reference in its entirety.

### TECHNICAL FIELD

The present disclosure relates to a method and apparatus for designing a powertrain system architecture for a mobility apparatus based on an allowable failure rate of a system and reliability.

More specifically, the present disclosure relates to a method and apparatus for designing the powertrain system architecture for the mobility apparatus, which implements an (e.g., aircraft) system architecture design and process by evaluating reliability of aircraft performance degradation due to failure while satisfying specifications for the mobility apparatus.

### BACKGROUND

With the advance of technologies, various transportation mobility apparatuses are emerging. In order to improve ground traffic congestion and address urban environment deterioration, advanced air mobility (AAM) apparatuses are being actively developed. The AAM apparatuses may move to a specific point within a complex urban area and provide services linked with other types of mobility apparatuses, such as ground mobility apparatuses.

An AAM aircraft may be different from an existing aircraft in terms of design requirements and operational and mission characteristics. AAM aircraft are being developed using an electric propulsion system for low noise and eco-friendliness to operate within or between urban areas. However, reliability evaluation and performance analysis for fossil fuel-based aircraft are not suitable for electric propulsion-based aircraft. Specifically, a failure rate and/or evaluation of fossil fuel-based aircraft does not reflect a failure rate of an electric aircraft (e.g., with standard and unique characteristics).

### SUMMARY

The present disclosure is directed to providing a method and apparatus for designing a powertrain system architecture for a mobility apparatus, which implements a robust aircraft system architecture design and process and improves the reliability of evaluation of aircraft performance degradation due to failure while satisfying standards (e.g., new requirements) for an aircraft.

The present disclosure is not limited to the objects mentioned above, and other objects that are not mentioned may be understood by those skilled in the art to which the present disclosure provides.

According to the present disclosure, there is provided a method for designing a powertrain system architecture for a mobility apparatus based on an allowable failure rate of a system and reliability. The method includes generating an available power rate under failure of a system based on a failure scenario established for a system architecture of an aircraft including a plurality of components according to a failure of components in the system architecture, generating a system reliability according to the failure scenario based on a failure rate of the component and a connection combination between the components of the system architecture, determining severity data of the system related to the available power rate under failure, based on risk level data indicating a correlation between a risk level and a power reduction rate of the system according to the available power rate under failure, and determining whether to adopt the system architecture based on an allowable failure rate of the system corresponding to the severity data and the system reliability.

According to the example embodiment of the method of the present disclosure, the plurality of components may be configured so that at least one of the components is allocated to each of a plurality of component types. The component type includes a thrust source configured to generate thrust of the aircraft, a power source configured to transmit power to the thrust source, an energy source configured to supply electrical energy to the power source, and a distribution device configured to manage power at least between the power source and the energy source. The failure scenario may be provided based on a failure of at least one component belonging to the component type.

According to the example embodiment of the method of the present disclosure, the plurality of components may be configured to have at least one component for each of a plurality of component types, and the generating of the system reliability includes identifying at least one faulty component designated in the failure scenario and the component type to which the faulty component belongs, generating a first reliability of a component type including the faulty component and a second reliability of another component type including a normal component, based on the connection combination of the component types, and generating the system reliability based on the first reliability and the second reliability.

According to the example embodiment of the method of the present disclosure, when the connection combination is formed by connecting homogeneous components in parallel to implement redundancy of the homogeneous components in the component type, the faulty components may be identified as a portion of the redundant components, and the first reliability may be generated using a reliability calculation process based on the number of normal components among the redundant components.

According to the example embodiment of the method of the present disclosure, the risk level data and the severity data may be provided for each of a plurality of performance indices. The performance indices are a takeoff distance of the aircraft, a climb gradient of the aircraft, and cruising capability of the aircraft. The cruising capability includes at least one of a cruising climb gradient and left energy to a specific point, and the risk level may include a plurality of risk levels classified for each of the performance indices.

According to the example embodiment of the method of the present disclosure, the allowable failure rate may be provided for each of the plurality of performance indices, and the determining of whether to adopt the system architecture may include adopting the system architecture satisfying (e.g., all) selection condition(s) of the system reliability for the allowable failure rate for each of the performance indices.

According to the example embodiment of the method of the present disclosure, the allowable failure rate of the system may be set for each of a plurality of certification levels classified depending on the number of passengers on board the aircraft, a maximum takeoff weight of the aircraft, and a propulsion scheme for the aircraft.

According to the example embodiment of the method of the present disclosure, the determining of whether to adopt the system architecture may include selecting the system architecture that satisfies selection condition of the system reliability based on the allowable failure rate, and adopting the system architecture that satisfies an adoption condition based on the number of connections between the components in the connection combination from selected system architectures.

According to the example embodiment of the method of the present disclosure, the method may further comprise, prior to the generating of the available power rate under failure of the system, receiving input data for the aircraft design, and performing sizing processing on the input data to generate a set of the system architectures based on the input data. The input data may comprise top-level information, aircraft data, and component data. The top-level information may include detailed information related to an electric propulsion-based system. The detailed information may include environment information, market information, operation information, performance information, and mission information. The environment information may be related to environmental pollution reduction and noise. The market information may include the number of passengers of the aircraft, an internal space of the aircraft, a loadable baggage weight, and a baggage space. The operation information may include a wing span and operational meteorological conditions, the performance information includes a speed, payload, maximum travel distance, takeoff and landing distances, operational target altitude, and climb gradient of the aircraft. The mission information may include a mission plan and mission scenario of the aircraft. The aircraft data may include an aircraft configuration and aerodynamic data of the aircraft. The component data may include an energy density, power density, and efficiency of components related to the propulsion system of the aircraft.

According to the example embodiment of the method of the present disclosure, sizing may include generating a set of the system architectures including a combination of the components, in accordance with functional decomposition based on the top-level information, the aircraft data, and the component data.

According to another example embodiment of the present disclosure, provided is an apparatus for designing a powertrain system architecture for a mobility apparatus based on an allowable failure rate of a system and reliability. The apparatus comprising a memory configured to store at least one instruction, and at least one processor configured to execute the at least one instruction stored in the memory. The at least one processor is configured to generate an available power rate under failure of a system based on a failure scenario established for a system architecture of an aircraft including a plurality of components according to a failure of components in the system architecture, generate a system reliability according to the failure scenario based on a failure rate of the component and a connection combination between the components of the system architecture, determine severity data of the system related to the available power rate under failure, based on risk level data indicating a correlation between a risk level and a power reduction rate of the system according to the available power rate under failure, and determine whether to adopt the system architecture based on an allowable failure rate of the system corresponding to the severity data and the system reliability.

The features briefly summarized above for the present disclosure are example aspects of the detailed description of the disclosure, and are not intended to limit the scope of the disclosure.

### BRIEF DESCRIPTION OF THE DRAWINGS

The above and other objects, features and advantages of the present invention will become more apparent by describing example embodiments thereof in detail with reference to the accompanying drawings, in which:

FIG. 1 is a diagram schematically illustrating modules of a design device for aircraft powertrain system architecture according to an example embodiment of the present disclosure;

FIG. 2 is a flowchart of a method for designing an aircraft powertrain system architecture according to an embodiment of the present disclosure;

FIG. 3 is a diagram illustrating a process related to the method for designing an aircraft powertrain system architecture;

FIG. 4 is a diagram illustrating a functional decomposition for a combination of components of the system architecture;

FIG. 5 is a diagram illustrating component sources of the architecture and a connection of the sources;

FIG. 6 is a diagram illustrating a combination relationship of the components according to functional decomposition;

FIGS. 7A, 7B, and 7C are diagrams illustrating various architecture sets according to the combination relationship of the components;

FIG. 8 is a diagram illustrating an available power rate under failure of a system for each failure scenario;

FIG. 9 is a diagram illustrating a concept of generation of system reliability;

FIG. 10 is a diagram illustrating a takeoff distance and a climb gradient as performance indices;

FIGS. 11A, 11B and 11C are diagrams illustrating risk level data for each performance index of takeoff length, climb gradient, and cruising, respectively;

FIG. 12 is a diagram illustrating an allowable failure rate of the system; and

FIG. 13 is a diagram illustrating an example in which a final system architecture is selected from among system architectures that satisfy the allowable failure rate.

### DETAILED DESCRIPTION

Hereinafter, example embodiments of the present disclosure will be described in detail with reference to the accompanying drawings so that those skilled in the art may implement the present disclosure. However, the present disclosure may be implemented in various different ways, and is not limited to the example embodiments described therein.

In describing example embodiments of the present disclosure, conventional functions or constructions may not be described in detail to prevent unnecessarily obscuring the understanding of the present disclosure. The same constituent elements in the drawings are denoted by the same or similar reference numerals, and a repeated description of the same elements may be omitted.

In the present disclosure, when an element is referred to as being “connected to”, “coupled to” or “linked to” another element, this may provide that an element is “directly connected to”, “directly coupled to” or “directly linked to” another element or is connected to, coupled to or linked to another element with the other element intervening therebetween. In addition, when an element “includes” or “has” another element, this may provide that one element may further include another element without excluding another component unless specifically stated otherwise.

In the present disclosure, the terms first, second, etc. are used to distinguish one element from another and do not limit the order or the degree of importance between the elements unless specifically mentioned. Accordingly, a first element in an embodiment could be termed a second element in an embodiment, and, similarly, a second element in an embodiment could be termed a first element in an embodiment, without departing from the scope of the present disclosure.

In the present disclosure, elements that are distinguished from each other are for describing each feature, and do not necessarily provide that the elements are separated. That is, a plurality of elements may be integrated in one hardware or software unit, or one element may be distributed and formed in a plurality of hardware or software units. Therefore, even if not mentioned otherwise, such integrated or distributed embodiments are included in the scope of the present disclosure.

In the present disclosure, elements described in various embodiments do not necessarily provide essential elements, and a portion of them may be optional elements. Therefore, an embodiment composed of a subset of elements described in an embodiment may also included in the scope of the present disclosure. In addition, embodiments including other elements in addition to the elements described in the various embodiments are also included in the scope of the present disclosure.

Features of the present invention and the way of attaining them will become apparent with reference to example embodiments described below in detail in conjunction with the accompanying drawings. Embodiments, however, may be embodied in many different forms and should not be constructed as being limited to example embodiments set forth herein. Rather, these example embodiments are provided so that this disclosure will convey the scope of the present disclosure to those skilled in the art.

In the present disclosure, each of phrases such as “A or B”, “at least one of A and B”, “at least one of A or B”, “A, B or C”, “at least one of A, B and C”, “at least one of A, B or C”, and/or “at least one of A, B, C or combination thereof” may include any one or all possible combinations of the items listed together in the corresponding one of the phrases.

In the present disclosure, expressions of location relations used in the present specification such as “upper”, “lower”, “left” and “right” are employed for the convenience of explanation, and in case drawings illustrated in the present specification are inversed, the location relations described in the specification may be inversely understood.

Hereinafter, example embodiments of the present disclosure will be described with reference to the accompanying drawings.

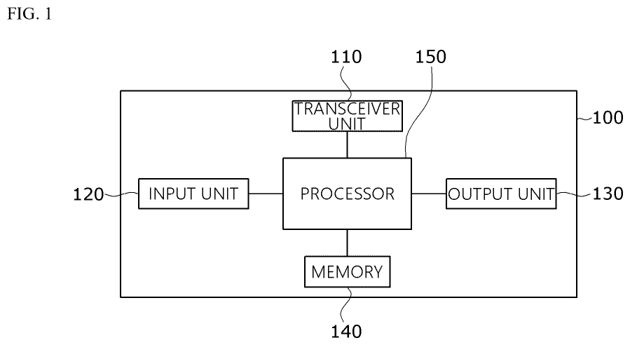

Hereinafter, an example embodiment of the present disclosure, that is, a design device for an aircraft powertrain system architecture based on an allowable failure rate of a system and reliability, will be described with reference to FIG. 1. FIG. 1 is a diagram schematically illustrating modules of the design device for aircraft powertrain system architecture according to the embodiment of the present disclosure. In the present disclosure, the device is described as designing the powertrain system architecture for the aircraft, but the device may also be referred to as a device that design(s) the powertrain system architecture for a mobility apparatus moving to a predetermined place or location. The mobility apparatus may include, for example, an aircraft and/or a ground vehicle or a ship.

A design device for aircraft powertrain system architecture 100 may be a device that evaluates performance resulting from a failure of at least one of a plurality of components of an aircraft to ascertain severity, and designs and selects a system architecture of the aircraft based on an allowable failure rate and the severity for system reliability. The system architecture may include a plurality of components and may be an overall structure of an aircraft operated as a combination of the plurality of components. An aircraft for which a system architecture is provided may be an existing legacy aircraft, but also may be an air mobility, such as an AAM aircraft, but is not limited thereto. The air mobility may be different from a legacy aircraft in terms of a propulsion scheme, takeoff and landing scheme, fuselage structure, and/or the like.

Although an aircraft system architecture based on an electric propulsion system is primarily described in the present disclosure, the present disclosure may be applicable to another type of propulsion system for an aircraft. In the case of another type of propulsion system, the design device 100 may design or select a system architecture suitable for the system using specifications (e.g., requirements) for the system, data, and information on components related to the other type of propulsion system. The specifications (e.g., requirements), the data, and the information may include, for example, input data related to design specifications (e.g., requirements) and certification, failure rate and/or failure scenarios of components, risk level data, and an allowable failure rate of the system, but are not limited thereto.

Hereinafter, for convenience of description, the design device for aircraft powertrain system architecture 100 may simply be called a design device.

The design device 100 may include a transceiver unit 110, an input unit 120, an output unit 130, a memory 140, and a processor 150. The design device 100 may be a computing device and may be a device that holds software for evaluating and selecting at least one aircraft system architecture on a non-transitory storage medium. The design device 100 may be provided by a local computer or a cloud server.

The transceiver unit 110 may transmit and receive data to and from an external device, support mutual communication to acquire external data in the present disclosure, and exchange data with a device that holds or manages the external data. The device may be, for example, at least one server that manages various types of information related to an aircraft.

The server may be, for example, an external device that provides input data for design of an aircraft system. The design device 100 may receive the input data from the server according to a user request or search. The input data may include top-level information, aircraft data, and component data. The server may hold data related to a failure rate of a component, risk level data used to determine severity data, and information related to an allowable failure rate of a system utilized to adopt a system architecture. The transceiver unit 110 may receive the data and the information from the server and transmit the data and the information to the memory 140 and the processor 150. The input data, component failure rate, risk level data, and information related to an allowable failure rate will be described herein.

The input unit 120 may be an input interface that receives a user's request or the input data. The interface may be a hardware or software interface. The hardware interface may be, for example, a keyboard or a mouse, and the software interface may be a graphic user interface on a display provided by the output unit 130.

The output unit 130 may output a response to the user's request or the input data visually, audibly, or tactilely. The output unit 130 may be, for example, a display, a speaker, or a tactile sensing device.

The memory 140 may store an application and various pieces of data for operating the design device 100, and load the application or read or record the data in response to a request from the processor 150. Further, the memory 140 may hold various pieces of data related to the design of the aircraft system architecture performed in the design device 100. The data includes, for example, input data, a component failure rate, risk level data, and information related to an allowable failure rate, but is not limited thereto.

In the present disclosure, the processor 150 may (e.g., perform processing for) design a system architecture by evaluating and selecting a plurality of aircraft system architectures using applications, instructions, and data stored in the memory 140.

Specifically, in relation to the present disclosure, the processor 150 may perform processing for generating problem definition data according to a user's (e.g., requirement) specification. For example, the problem definition data may include (e.g., required) aircraft performance metrics such as range or payload capacity, specific mission profiles to be supported by the aircraft, and allowable operational or environmental constraints. The processor 150 may size the input data received for an aircraft design to generate a set of system architectures based on the input data. The processor 150 may generate an available power rate under failure of the system based on a failure scenario established for the system architecture according to a failure of a component in the system architecture of an aircraft including a plurality of components. The processor 150 may generate system reliability according to the failure scenario based on a failure rate of the component and a combination of connections between the components of the system architecture. The processor 150 may determine the severity data of the system for the available power rate under failure based on risk level data indicating a correlation between a risk level and a power reduction rate of the system according to the available power rate under failure. The processor 150 may determine whether to adopt the system architecture based on the allowable failure rate of the system corresponding to the severity data and the system reliability.

The processor 150 may be implemented as a single processing module, for example. As another example, the processing described herein may be distributed and processed in a plurality of processing modules, which may be collectively referred to as the processor 150 in the present disclosure.

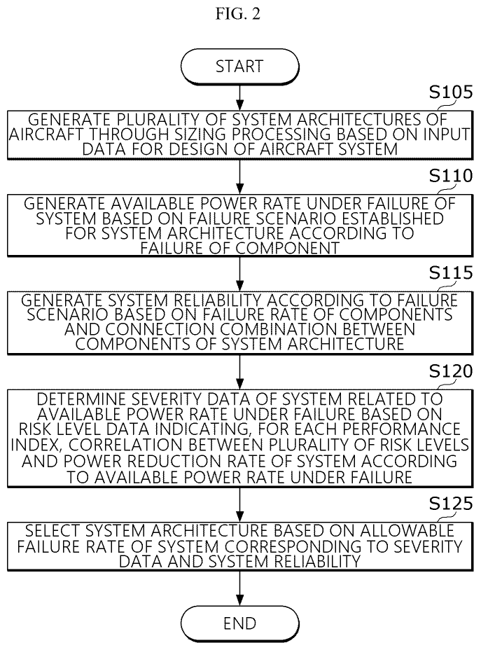

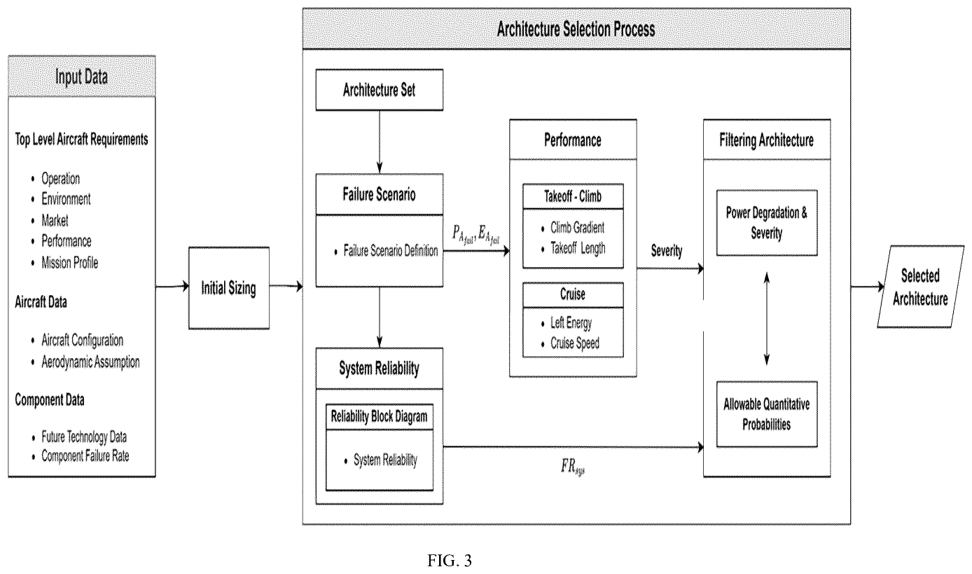

Hereinafter, a method according to an example embodiment of the present disclosure, that is, a method for designing an aircraft powertrain system architecture based on an allowable failure rate of a system and reliability, which is performed by the design device 100, will be described with reference to FIGS. 2 and 3. FIG. 2 is a flowchart of a method for designing an aircraft powertrain system architecture according to the embodiment of the present disclosure. FIG. 3 is a diagram illustrating an (e.g., entire) process related to the method for designing an aircraft powertrain system architecture.

In the present disclosure, respective modules of the design device 100 perform a process of the method, but for convenience of description, each module that performs the process may be described interchangeably as the design device 100.

First, the processor 150 of the design device 100 may generate a plurality of system architectures of the aircraft through sizing processing based on the input data for design of the aircraft system (S105).

The input data may be provided by the user input or memory 140. The input data may include top-level information, aircraft data, and component data, as described above in FIG. 1.

In order to perform performance analysis for an eco-friendly AAM aircraft, sizing may be performed (e.g., by the processor). The sizing may be executed to reflect the eco-friendliness of the AAM. A system of the aircraft closely related to eco-friendliness is a propulsion system, and may be different from sizing used in a design of an internal combustion engine aircraft. In sizing used in the present disclosure, a battery that stores electric energy of an electric propulsion system that does not generate pollutants such as NOx and CO₂, and a fuel cell that generates electric energy may be considered.

In an example of the input data according to the above-described matter, the top-level information may include detailed information related to an electric propulsion-based system. The top-level information may be referred to as top-level aircraft requirements (TLAR) or specifications. The detailed information may include at least one of environment information, market information, operation information, performance information, and mission information.

The environment information may be related to, for example, environmental pollution reduction and noise. The environment information may be, for example, pollutant emissions, energy consumption, and noise level limits required for an electric aircraft, for example, in the case of an electric propulsion-based aircraft. The market information may be data for determining a category of an aircraft. The market information may include, for example, the number of passengers of the aircraft, an internal space of the aircraft, a loadable baggage weight, and a baggage space. The operation information may include, for example, a wing span and operational meteorological conditions. The performance information may include minimum performance in the design of the aircraft. The performance information may include, for example, aircraft speed, payload, maximum travel distance, takeoff and landing distances for an aircraft type, operational target altitude, and a climb gradient. When the aircraft is an AAM, an aircraft type may be, for example, conventional takeoff and landing (CTOL), short takeoff and landing (STOL), and vertical takeoff and landing (VTOL). The mission information may include, for example, a mission plan and mission scenario of the aircraft. The mission plan may be, for example, takeoff, landing, cruising, and climbing. The mission information may vary depending on an aircraft to be designed.

The aircraft data may include, for example, an aircraft configuration and aerodynamic data of the aircraft. In relation to the aircraft configuration, it may be challenging to provide specific (e.g., aircraft) shape information. Thus, several aircraft types, similar to a targeted aircraft, may be collected, and data related to the aircraft configuration may be provided. For example, the aircraft configuration may be provided by utilizing configuration characteristics, specifications, and standards of the aircraft. The aerodynamic data is provided as an assumed value, and may include lift and drag coefficients of an aircraft wing. The aerodynamic data may be used to calculate drag and (e.g., required) thrust during the operation of the aircraft.

The component data may be related to an internal propulsion system of the aircraft. In order to overcome the drag of the aircraft and fly forward, a force greater than the drag may be required. When thrust or power (e.g., required) for an aircraft operation is calculated, a weight of the component may be calculated. Accordingly, the component data may include, for example, an energy density, power density, and/or efficiency of the component related to the propulsion system of the aircraft. Specifically, the component data may be data of a component related to a powertrain system. The powertrain system may include, for example, components related to thrust, power that generates the thrust, energy that generates the power, and a distribution system that manages the power and the energy.

Even though a failure rate of the component may have little relevance to the sizing, the failure rate may be utilized for the generation of a failure rate and system reliability of the system architecture.

The sizing may be performed by the processor 150 using the input data to generate a set of system architectures based on the input data.

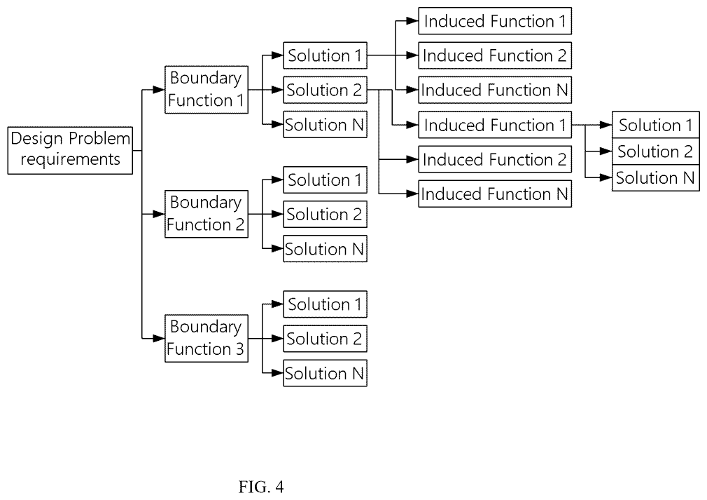

The sizing may include generating a set of system architectures including a combination of components, based on functional decomposition based on the top-level information, the aircraft data, and the component data. Specifically, components belonging to various system architectures may be determined through the sizing. The sizing will be described in an example of FIG. 4, in which functions (a boundary function in FIG. 4) of solving requirements (problem requirement in FIG. 4) derived from the top-level requirement (TLAR) or specification are listed, and then components (solution in FIG. 4) that perform the functions may be listed in lower items. FIG. 4 is a diagram illustrating a functional decomposition for a combination of components of the system architecture. Detailed functions for an operation of components corresponding to lower items may be presented.

The combination of the components may constitute the system architecture. Selection of components for a combination may include selecting, for example, a combination from which a minimum value is derived in relation to an expected manufacturing cost and weight of an aircraft or a system architecture having the performance chosen or desired by the user from various system architectures.

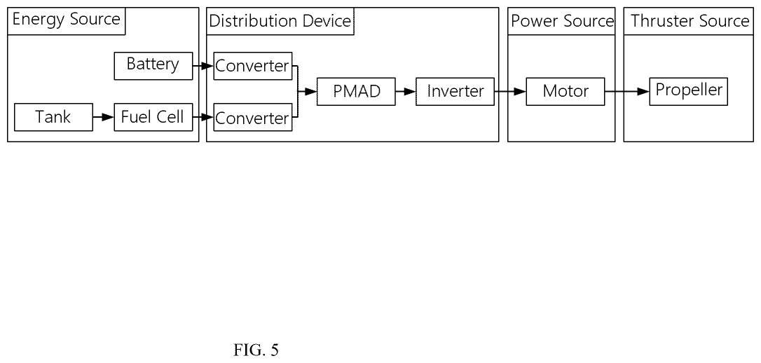

For the combination of the components, the components may be grouped according to a component type provided (e.g., defined) by functions of the components. A plurality of components may be configured so that at least one of the components is allocated to each of a plurality of component types. As illustrated in FIG. 5, the component types may include a thrust source that generates thrust of the aircraft, a power source that transmits power to the thrust source, an energy source that supplies electrical energy to the power source, and a distribution device that manages power at least between the power source and the energy source. FIG. 5 is a diagram illustrating component sources of the architecture and a (e.g., basic) connection of the sources. PMAD illustrated in FIG. 5 may be Power Management and Distribution. As illustrated in FIG. 5, respective sources may be connected in an order in which operations and functions of the system architecture are implemented so that a functional connection relationship can be established. Specifically, the thrust source may be connected to the power source. The energy source may be connected to the power source via the distribution device or may be directly connected to the power source. In FIG. 5, the component type is related to a powertrain system of the aircraft, but is not limited thereto, and may be related to various systems of the aircraft.

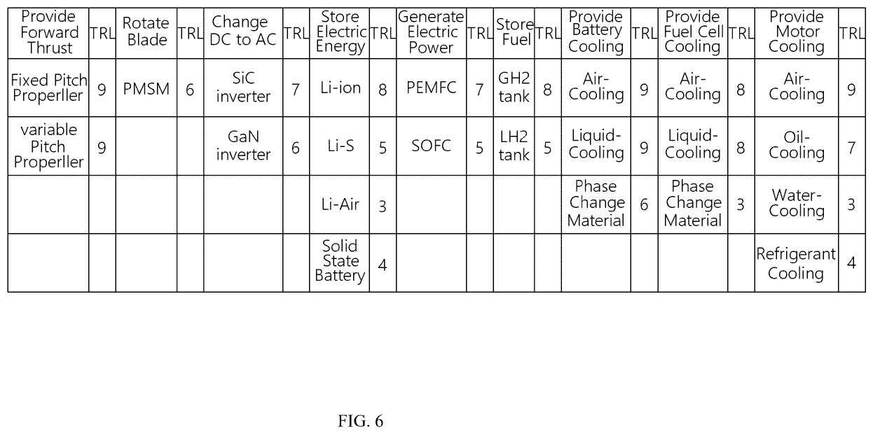

The component responsible for a function of each source (or component type) may be assigned according to an arrangement order of the component types. As illustrated in FIGS. 5 and 6, components related to the respective sources, that is, the respective component types, are employed in combination, and a plurality of system architectures may be generated according to the combinations of the components. FIG. 6 is a diagram illustrating a combination relationship of the components according to functional decomposition.

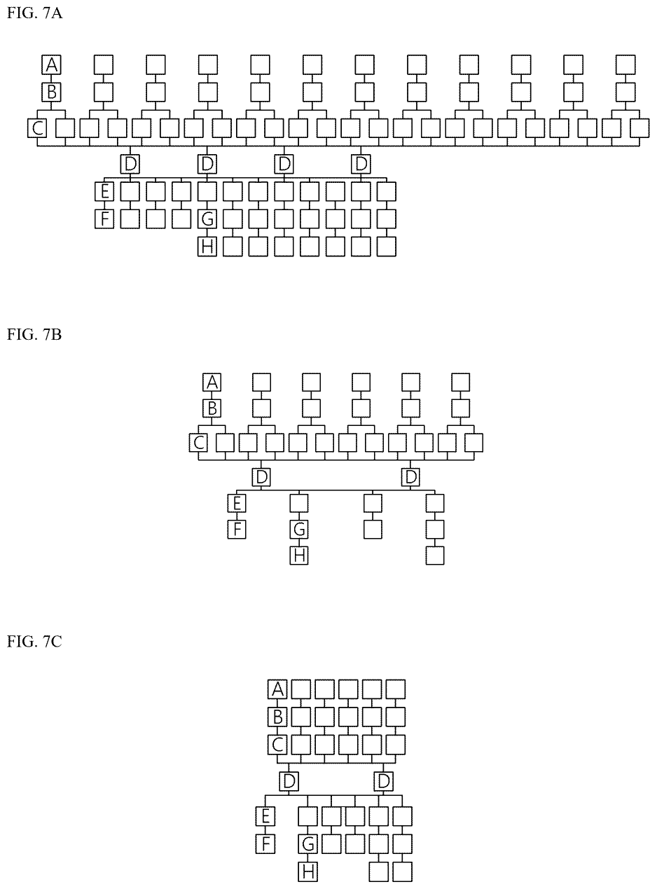

A set of a plurality of system architectures generated by the sizing (e.g., via the processor) may be illustrated as in FIGS. 7A-7C. FIGS. 7A-7C are diagrams illustrating various architecture sets according to the combination relationship of the components. In FIGS. 7A-7C, components related to A, B, C, D, E, F, G, and H may indicate a propeller, a motor, an inverter, PMAD, a converter, an electric battery, a fuel cell, and a tank for a fuel cell, respectively. In FIGS. 7A-7C, boxes arranged horizontally with respect to boxes with A to E are the same components as A to E, boxes with the same color as boxes with F and G are the same components as F and G, and boxes connected to G are fuel cell tanks. Referring to FIGS. 7A-7C, the connection combination between the components may be a series or parallel connection. For example, the propeller, the motor, the inverter, the PMAD, the converter, and the electric battery may be connected in series for implementation of functions, and the propeller, the motor, the inverter, the PMAD, the converter, the fuel cell, and the tank may be connected in series. In addition to the example of FIGS. 7A-7C, the fuel cell may be connected in series with the electric battery. The series connection of FIGS. 7A-7C may be established with reference to the connection for implementation of the functions in FIG. 5. Referring to FIGS. 7A and 7B, two inverters may be connected in parallel to one motor for redundancy. Referring to FIGS. 7A to 7C, a plurality of electric batteries or a plurality of fuel cells may be connected in parallel to a plurality of inverters via the PMAD for redundancy. That is, a system architecture formed by connecting homogeneous components in parallel may be created to implement redundancy of the same components in the component type. A system architecture with a redundant structure may be generated according to the input data, such as safety requirements corresponding to component failure or flight abnormality requested from the top-level information, and redundant design specifications (e.g., requirements).

Referring to FIGS. 2 and 3, the processor 150 of the design device 100 may generate an available power rate under failure of a system based on a failure scenario established for a system architecture according to the failure of the component (S110).

The failure scenario may be provided based on the failure of at least one component belonging to the component type. When the components of the system architecture fail, the system architecture, that is, failure of available power that can be output from the aircraft, may be generated.

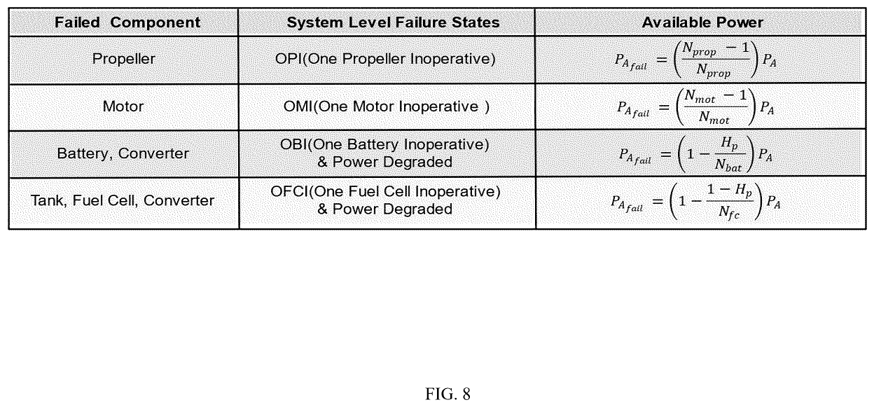

The failure scenario may be divided into scenarios for one propeller inoperative (OPI), one motor inoperative (OMI), one battery or converter inoperative (OBI), and one tank, fuel cell, or converter inoperative (OFCI), as illustrated in FIG. 8. FIG. 8 is a diagram illustrating the available power rate under failure of the system according to the failure scenario. In an electric propulsion-based aircraft system, a single faulty component is provided (e.g., defined as a state) from the perspective of the entire system, and an equation expressing the available power failure for each faulty component may be provided.

In FIG. 8, P_{A} may represent available normal power in a normal state of the component, Nₓₓ may represent the number of components, and xx may be the name of a component. P_{Afail} may be the available power failure of the system architecture in each failure scenario. When a plurality of homogeneous energy modules (for example, electric batteries) are used in the energy source, the available power may differ depending on Hₚ. Hₚ may represent a power distribution ratio of two energy modules and may be expressed as

$${H}_{p} = \frac{{P}_{b a t}}{{P}_{t o t a l}} .$$

In the case of a failure scenario Ptotal in which both batteries and fuel cells are used and one battery fails, the available power failure may be available power shown in OBI. In the case of a failure scenario in which both batteries and fuel cells are used and one fuel cell fails, the available power failure may be available power shown in OFCI. When there are no fuel cells in the system architecture and only batteries are used, an equation for the reduced power P_{Afail} may be expressed by the same equation (the equation of OPI or OMI) as that of the propeller and the motor. In the system architecture of FIG. 7A, the available power failure of OPI may be

$${P}_{{A}_{fail}} = {P}_{A} * ( \frac{11}{12} ) ,$$

and the available power failure of OMI may be

$${P}_{{A}_{fail}} = {P}_{A} * ( \frac{11}{12} ) .$$

Further, the available power failure of OBI may be

$${P}_{{A}_{fail}} = {P}_{A} * ( 1 - \frac{{H}_{p}}{4} ) ,$$

and the available power failure of OFCI may be

$${P}_{{A}_{fail}} = {P}_{A} * ( 1 - \frac{1 - {H}_{p}}{8} ) .$$

The numbers of components of the system architecture of FIG. 7A are Nₚᵣₒₚ=Nₘₒₜ=12, Nᵢₙᵥ=24, N_{pmad}=4, N_{conv}=12, N_{bat}=4, N_{fc}=Nₜₐₙₖ=8.

In the case of the propulsion system, the types of components that are configured may be diverse depending on, for example, a level and specifications (e.g., requirements) of a designed aircraft. In the case of the electric propulsion system, a system architecture with no DC-DC converter may be created, or a system architecture with additional components such as a generator or gearbox may be created. There may be limitations in analyzing failure states of various system architectures described above. Among components derived from the functional decomposition, common components or components (e.g., critically) considered by the user may be (e.g., preferentially) interpreted. According to the present disclosure, with an equation using H_{P} and the number of components, available failure power of the electric propulsion system may use a battery as a component of an energy source and also may use heterogeneous energy components, that is, a fuel cell and a battery, may be generated.

Referring to FIGS. 2 and 3, the processor 150 may generate the system reliability according to the failure scenario based on a failure rate of the components and a connection combination between the components of the system architecture (S115).

A detailed process of operation S115 will be described, and when there is at least one component for each of a plurality of component types, the processor 150 may identify at least one faulty component designated in the failure scenario and a component type to which the faulty component belongs.

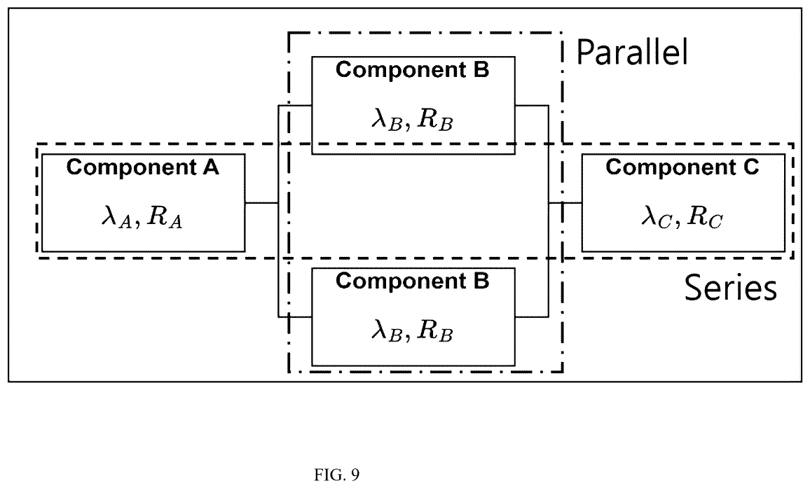

Generation of system reliability will be described below. FIG. 9 is a diagram illustrating the concept of generation of system reliability. The failure rate and operating time of the components may be used to calculate the system reliability. After the reliability of the components is generated, the system reliability may be calculated according to a connection combination and situation of the system architecture.

It may be assumed that the reliability is constant over time, and systems other than the propulsion system related to the components included in the system architecture may not be considered. The reliability of a single component may be expressed as R(t)=e^{-λt}. λ is the failure rate of the component, and may be a failure frequency corresponding to the number of failures per unit time of the component. R is the reliability of a single component, and t may be the operating time (or flight time).

The system reliability may be generated using a reliability block diagram, as illustrated in FIG. 9. When the connection combination is a series connection, system-related reliability may be calculated as a product of the reliabilities of the respective components surrounded by a dotted line. For example, the reliability may be calculated as R_{SYS}=R_{A}×R_{E-Parallel}×R_{c}. When the connection combination is a parallel connection, the reliability surrounded by a dash-dot line may be calculated as R_{B-Parallel}=1−(1−R_{B})².

In relation to the detailed process of operation S115, the processor 150 may generate a first reliability of a component type including a faulty component and a second reliability of another component type including a normal (e.g., non-faulty) component, based on the connection combination of the component types. For example, the normal component may, as exemplified in FIG. 8, be a component that may output available normal power P_{A} in a normal state. When the connection combination is configured as a parallel connection of components for redundancy, the faulty components may be identified as a portion of the redundant components. The first reliability may be generated using a reliability calculation process based on the number of normal components among the redundant components.

The generation of the first and second reliabilities are provided herein, and in order to increase the system reliability, a redundant design may be considered with a (e.g., main) purpose to provide (e.g., ensure) that there is no abnormality in function even when one of the homogeneous components fails. For example, four homogeneous components may be connected in parallel to create a system architecture so that, even when one component fails, three components operate and the entire system operates normally.

When any component fails, a reliability calculation process may be applied to generate the failure probability and system reliability from the system perspective. The reliability calculation process is a k-out-of-n scheme, and Equation 1 below may be used. When one component out of N components fails, the system reliability may be calculated using an R value when k=n−1.

$$R ( k , n ) = {\sum }_{i = k}^{n} ( \begin{matrix}n \\ i\end{matrix} ) {p}^{i} {q}^{n - i} \qquad [ Equation 1 ]$$

In Equation 1, n is the number of components, i is the number of normally operating components, p is the reliability of the component, and q=1−p.

In order to generate the system reliability according to the reliability calculation process, reliability may be generated for each component type. For the system architectures illustrated in FIGS. 5 to 7, reliabilities of the thrust source, the power source, the energy source, and the distribution device may be generated first. When one component in the power source fails and components of other component types are normal, reliabilities Rₜₛ, Rₚₛ, Rₑₛ, and R_{ds} of the thrust source, the power source, the energy source, and the distribution device may (e.g., all) be multiplied by using the reliability Rₚₛ(n−1,n) of the power source. Here, the reliability of the component type including the faulty component may be the first reliability, and the reliability of each component type including the normal component may be the second reliability. When components belonging to the component type are connected in series or in parallel, an energy flow is regarded as a series connection, and the system reliability may be calculated as R_{sys}=Rₑₛ*Rₚₛ*R_{ds}*Rₜₛ. That is, the processor 150 may generate system reliability based on the first reliability and the second reliability.

An example in which the system reliability according to the failure scenario in the system architecture of FIG. 7A is generated is described herein. For example, the number of components of the system architecture in FIG. 7A is Nₚᵣₒₚ=Nₘₒₜ=12, Nᵢₙᵥ=24, N_{pmad}=4, N_{conv}=12, N_{bat}=4, N_{fc}=Nₜₐₙₖ=8, as described above.

When there is no abnormality in the operation of the system architecture, the reliability of each component type may be as shown in Table 1 below.

TABLE 1

| Source | Equation |
|---|---|
| Energy Source | R_{ES} = (R_{bat}R_{conv} )⁴ (RₜₐₙₖR_{fc}R_{conv} )⁸ |
| Distribution Source (If 3 out-of-4 is used) | ${R}_{D S} = {\sum }_{i = 3}^{4} ( \begin{matrix}4 \\ 3\end{matrix} ) {R}_{p m a d}^{3} ( 1 - {R}_{p m a d} ) = {R}_{p m a d}^{4} + 3 {R}_{p m a d}^{3} ( 1 - {R}_{p m a d} )$ |
| Power & Thruster | R_{PSTS} = (RₚᵣₒₚRₘₒₜ (1 − (1 − Rᵢₙᵥ)²))¹² |
| Source | |

The system reliability according to the failure of each component may be expressed as in the following Equations (the set of equations are referred to hereinafter as Equation 2). λ is the failure rate.

$${R}_{OPI} = {R}_{ES} * {R}_{DS} * {R}_{PSTS}^{12} + 12 \{ ( 1 - {R}_{prop} ) * {R}_{mot} * ( 1 - {( 1 - {R}_{inv} )}^{2} ) \} \qquad Equation 2$$

$${R}_{OMI} = {R}_{ES} * {R}_{DS} * [ {R}_{PSTS}^{12} + 12 \{ ( 1 - {R}_{mot} ) * {R}_{prop} * ( 1 - {( 1 - {R}_{inv} )}^{2} ) \}$$

$${R}_{OBI} = {R}_{DS} * {R}_{PSTS} * {R}_{{fc}_{sys}}^{8} * \{ {R}_{{bat}_{sys}}^{4} + 4 {R}_{{bat}_{sys}}^{3} * ( 1 - {R}_{{bat}_{sys}} ) \}$$

$${R}_{OFCI} = {R}_{DS} * {R}_{PSTS} * {R}_{{bat}_{sys}}^{4} * \{ {R}_{{fc}_{sys}}^{8} + 8 {R}_{{fc}_{sys}}^{7} * ( 1 - {R}_{{fc}_{sys}} ) \}$$

$${λ}_{cases} = \frac{ln ( {R}_{cases} )}{t}$$

Table 1 shows an equation for calculating the reliability when (e.g., all) component types are operating, which is an equation when it is assumed that there is no abnormality even when (e.g., only) three of four energy sources are operating in the case of power management and distribution (PMAD) belonging to the distribution device. There are 12 combinations of batteries and fuel cells belonging to the energy source. The reliability of the component type (energy source) when all the batteries and fuel cells are operating may be represented as in Table 1. This is a case in which (e.g., all) combinations of battery+converter and fuel tank+fuel cell+converter operate.

In a combination of the power source and the output source, the reliability of the component type when the inverter is connected in parallel thereto and (e.g., all) the sources operate may be described as in Table 1. Since there are a total of 12 combinations of two of the propeller, the motor, and the inverter, the reliability under full operation is given by the 12th power of the reliability of each of such sets.

It may be shown that there is no abnormality in operation even when (e.g., only) k of n components operate when an equation k-out-of-n is used. The equation k-out-of-n is applied (e.g., only) to a group of component types to which a faulty component belongs according to a fixed scenario of any one of OPI, OMI, OBI, and OFCI, and the reliability of the component type may be calculated. A group of other component types including the normal components may be calculated using the equation in Table 1.

In Equation 2, OBI corresponds to a failure of the battery belonging to the energy source, and the equation in Table 1 may be used for the distribution device, the power source, and the thrust source. The reliability R_{ES} of the energy source may be provided as in the above equation by applying a 3-out-of-4 system, which is a reliability allowing (e.g., all) eight fuel cell systems to operate and allowing one out of four batteries to fail, to the battery only.

According to the present disclosure, the system reliability may not be generated solely from component failures, but may be generated based on an influence from the perspective of the entire aircraft. Further, a system architecture having an electric propulsion system that operates even when any single component fails through parallel connection for improved stability may be considered as an evaluation target. Further, components included in the propulsion system, such as a fuel supply, an energy supply device, and a propeller, may be presented through functional decomposition, and the system reliability may be calculated by using failure rates of different components.

Referring back to FIGS. 2 and 3, the processor 150 may determine the severity data of the system related to the available power rate under failure based on the risk level data indicating a correlation between the risk level and the power reduction rate of the system according to the available power rate under failure (S120).

The risk level data may provide the correlation between the risk and the power reduction rate to allow the risk corresponding to the power reduction rate based on the available power rate under failure to be identified in at least one performance index. In the present disclosure, an example in which the risk level data is provided for a plurality of performance indices will be mainly described.

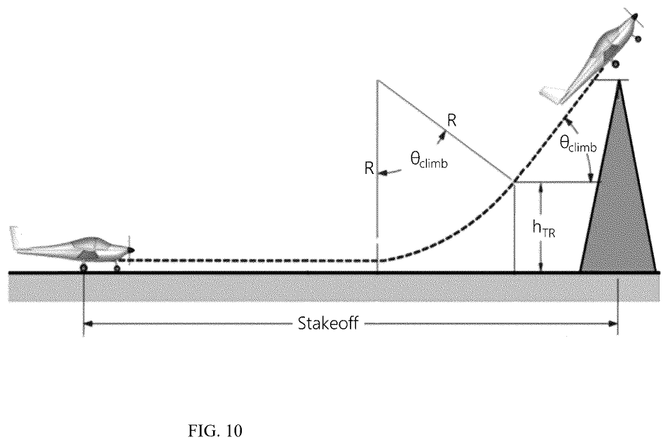

In a scenario related to an aircraft mission, sections that affect power or energy may be a takeoff section, a climb section, and a cruising section. Due to power reduction, the performance in the takeoff, climb, and cruising sections may be (e.g., greatly) reduced. Since the takeoff consumes the most power, a performance index related thereto may be a takeoff distance. The takeoff distance may be S_{takeoff}, as illustrated in FIG. 10. FIG. 10 is a diagram illustrating the takeoff distance and a climb gradient as performance indices. In the case of the climb section, the climb gradient may be used as the performance index. The climb gradient may be θ_{climb}. Since cruising is the section in which the most energy is consumed, a performance index related to cruising may be cruising capability for determining whether level flight is possible. Performance indices related to the cruising capability may be, for example, a cruising climb gradient and left energy allowing flight to a specific point. The specific point may be a point of departure, a destination point, or a point guided by control, which is close to a current location in emergency landing.

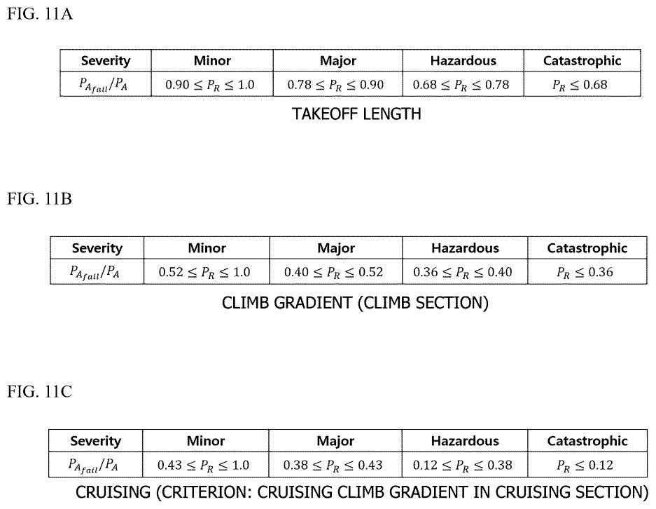

The risk level may be set based on, for example, an aircraft-related certification regulation, an aircraft-related standard criterion, and user requirements. The risk level may be classified into, for example, five risk levels from a minimum risk level to a maximum risk level. The risk level may be Negligible (not illustrated in FIGS. 11A to 11C), Minor, Major, Hazardous, or Catastrophic, as illustrated in FIGS. 11A to 11C, and the risk level may be changed to various names. FIGS. 11A, 11B and 11C are diagrams illustrating risk level data for each performance index.

An upper limit of the takeoff distance may be determined from requirements and a runway length of a plurality of actually operated airports. Among runway lengths of a plurality of airports, the runway length corresponding to a predetermined rank (or upper percentile) from a shortest length may correspond to the catastrophic risk level among the performance indices related to the takeoff distance. The takeoff distance may be set to be longer in the order of Hazardous, Major, Minor, and Negligible related to the takeoff distance.

Since a CTOL aircraft takes off via a runway and utilizes the full length of the runway, the risk level may correspond to Catastrophic when this runway length is exceeded during occurrence of a failure. Since a CTOL takeoff distance requirement is present in an initial performance specification (e.g., requirement), a value between a maximum runway length and a CTOL (e.g., required) runway length may be set as a takeoff distance during occurrence of a failure. In this case, takeoff is possible with the maximum runway length of (e.g., all) the runways of the airport, but a risk level related to an intermediate takeoff distance may correspond to Hazardous since a target requirement is not satisfied. When there is an STOL takeoff distance, the risk level may be Major because takeoff is possible on a general CTOL runway but not at an airport with a shorter runway.

In the case of the climb gradient, a certification level that should be satisfied may be determined depending on aircraft. For example, according to aviation certification regulations, different climb gradients may be presented depending on a case in which (e.g., all) power sources or propulsion systems are operating or a case in which there is a significant loss of thrust.

In relation to an (e.g., all) engines operating (AEO; all power sources and propulsion systems operating) condition, a (e.g., required) climb gradient may be 8.3% for certification level-1, 2/low-speed aircraft, and 4% for certification level-1, 2/high-speed aircraft or certification level-3, 4. In relation to a thrust loss condition, the climb gradient is 1.5% at an altitude of 1524 m for certification level-1, 2/low-speed aircraft, and 1% for certification level-1, 2/high-speed aircraft or certification level-3, 4. Here, the certification level may be classified into levels I to IV depending on the number of passengers on board the aircraft, a maximum takeoff weight of the aircraft, and a propulsion scheme for the aircraft. As the level increases, an allowable failure rate of the system described herein may be set to decrease. The allowable failure rate of the system may be set for each performance index.

Even when a failure occurs, if the climb gradient of 1.5% (level 3, 4), which is the AEO condition, is satisfied, the risk level may be designated as Minor. Since the Major risk level should satisfy a climb gradient of 1% or more when a loss of thrust occurs, the risk level of the climb gradient exceeding 1% and less than 1.5% may be designated as Major. The Hazardous risk level may have a positive climb gradient, but the climb gradient may be less than 1%. The Catastrophic risk level may be a risk level at which a greatest risk occurs since the climb gradient is negative and the aircraft cannot climb at all altitudes during the climb section.

In relation to a risk level of the cruising capability, when the level flight is possible by maintaining a cruising altitude presented in mission requirements, the risk level may be designated as Minor. When cruising flight can be performed after a decrease in the altitude due to inability to perform the level flight at the cruising altitude (that is, a non-positive climb gradient at the cruising altitude), the risk level may be designated as Major. When the cruising is difficult due to inability to perform the level flight while maintaining the altitude even after a decrease in the altitude, the risk level may be designated as Hazardous. When there is a mission of descent after cruising, but a descent gradient (or descent rate) presented in the mission requirements is not satisfied, the risk level may be designated as Catastrophic. The negative climb gradient may mean that a gentle descent is impossible.

FIGS. 11A to 11C illustrate a correlation of the power reduction rate (or available power rate under failure) of the system corresponding to the risk level described above for each performance index required in the takeoff, climb, and cruising sections. P_{A} is power available without a failure, and P_{Afail} may be power during occurrence of a failure. P_{Afail}/P_{A} may represent the available power rate under failure. A reduction level of available power is ascertained from the power reduction rate, and the greater the power reduction, the higher the risk level may be.

The takeoff distance, such as a maximum takeoff distance proposed in the requirements, is 1025.36 m, and when more than 32% of the available power is reduced (=P_{R}≤0.68), the takeoff distance greater than 1025.36 m may be derived through performance analysis. In the case of Hazardous, the takeoff distance is greater than 812.292 m but smaller than 1025.36 m, and a corresponding power reduction may be 22% when the takeoff distance is 812.292 m. When the power reduction is greater than 0.68 and smaller than 0.78, the risk level may be designated as Hazardous.

The processor 150 may identify the risk level presented in the risk level data for each performance index illustrated in FIGS. 11A to 11C, in relation to the power reduction rate related to the available power rate under failure of the system, and determine that each identified risk level is severity data for each performance index.

Referring back to FIGS. 2 and 3, the processor 150 may determine whether to adopt the system architecture based on the allowable failure rate of the system corresponding to the severity data and the system reliability (S125).

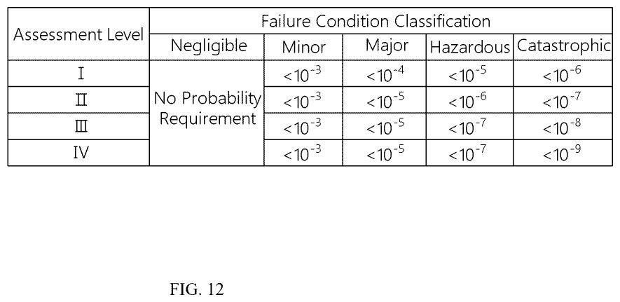

The allowable failure rate of the system, for example, may be set for each of a plurality of certification levels that are classified depending on the number of passengers on board the aircraft, a maximum takeoff weight of the aircraft, and a propulsion scheme for the aircraft. FIG. 12 is a diagram illustrating the allowable failure rate of the system. The allowable failure rate may be provided for each risk level and levels I to IV The number of passengers, the maximum takeoff weight, and the propulsion scheme (an electric system or turbine engine) may be provided (e.g., defined) based on certification regulations.

In addition, the allowable failure rate may be provided for each of the plurality of performance indices described in operation S120. The processor 150 may identify the risk level of the allowable failure rate corresponding to the severity data generated for each performance index (the risk level related to the allowable failure rate illustrated in FIG. 12) and identify the allowable failure rate at the identified risk level. The processor 150 may compare the identified allowable failure rate with the system reliability generated in operation S115 to determine whether selection condition(s) are satisfied. The selection condition may be, for example, that the system reliability is less than or equal to the allowable failure rate. The processor 150 may determine whether (e.g., all) selection condition(s) for the system reliability are satisfied for each performance index, and select the system architecture in which the selection condition(s) are satisfied, when (e.g., all) the selection condition(s) are satisfied.

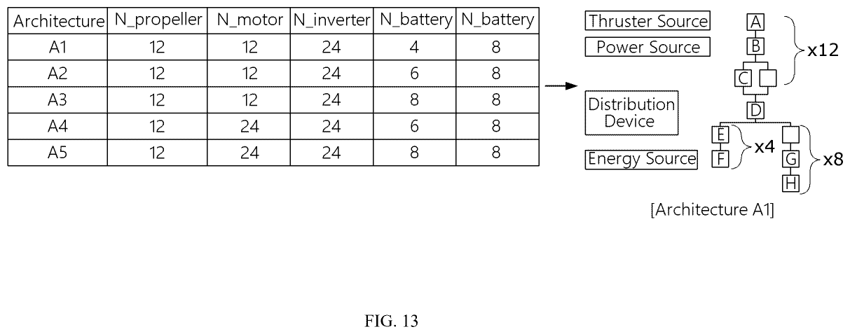

In addition, the processor 150 may adopt a system architecture in which the number of connections between the components in the connection combination satisfies an adoption condition from among the selected system architectures and output the system architecture through the output unit 130. The adoption condition is a system architecture having a minimum number of connections, as illustrated in FIG. 13, but is not limited thereto. FIG. 13 is a diagram illustrating an example in which a final system architecture is selected from among the system architectures that satisfy the allowable failure rate. A component serving as a power bus in an electric propulsion system may be a cable. Because a total length of the cable acts as an element that increases the weight of the aircraft, an improved system architecture may be designed with fewer (e.g., number of) connections between the components.

Since it may be challenging to initially confirm whether there is a safety problem due to an arbitrary number of operating components of the system architecture, the number of components cannot be specified. According to the present disclosure, it is possible to quantitatively determine the safety by determining the risk level of the system during the failure of each component based on the performance index from the number of components of the system architecture and power reduction using the failure scenario.

According to the present disclosure, it is possible to provide a method and apparatus for designing an aircraft powertrain system architecture, which may implement a robust aircraft system architecture design and process by improving the reliability of evaluation of aircraft performance degradation due to failure while satisfying (e.g., new) specifications (e.g., requirements) for an aircraft.

The effects of the present disclosure are not limited hereto, and other effects that are not mentioned may be understood by those skilled in the art from the above description.

While the example methods of the present disclosure described above are represented as a series of operations for clarity of description, it is not intended to limit the order in which the steps are performed, and the steps may be performed simultaneously or in different order as necessary. In order to implement the method according to the present disclosure, the described steps may further include other steps, may include remaining steps except for a portion of the steps, or may include other additional steps except for a portion of the steps.

The various embodiments of the present disclosure are not a list of (e.g., all) possible combinations and are intended to describe representative aspects of the present disclosure, and the matters described in the various embodiments may be applied independently or in combination of two or more.

In addition, various embodiments of the present disclosure may be implemented in hardware, firmware, software, or a combination thereof. In the case of implementing the present invention by hardware, the present disclosure can be implemented with application specific integrated circuits (ASICs), Digital signal processors (DSPs), digital signal processing devices (DSPDs), programmable logic devices (PLDs), field programmable gate arrays (FPGAs), general processors, controllers, microcontrollers, microprocessors, etc.

The scope of the disclosure includes software or machine-executable commands (e.g., an operating system, an application, firmware, a program, etc.) for providing (e.g., enabling) operations according to the methods of various embodiments that may be executed on an apparatus or a computer, a non-transitory computer-readable medium having such software or commands stored thereon and executable on the apparatus or the computer.

What is claimed is:

1. A method for designing a powertrain system architecture for a mobility apparatus, the method comprising:
generating an available power rate under failure of a system based on a failure scenario for a system architecture of the mobility apparatus including a plurality of components, wherein the available power rate failure is based on a failure of at least one component in the system architecture;
generating a system reliability according to the failure scenario based on a failure rate of the at least one component and a connection combination between the components of the system architecture;
determining severity data of the system, based on risk level data indicating a correlation between a risk level and a power reduction rate of the system based on the available power rate under failure; and
adopting the system architecture within the mobility apparatus based on an allowable failure rate of the system determined by the severity data and the system reliability.

2. The method for designing a powertrain system architecture of claim 1, wherein each of the plurality of components is allocated to a component type of a plurality of component types, the component types comprise
a thrust source configured to generate thrust of the mobility apparatus, a power source configured to transmit power to the thrust source, an energy source configured to supply electrical energy to the power source, and a distribution device configured to manage power between the power source and the energy source, and the failure scenario is based on a failure of the at least one component.

3. The method for designing a powertrain system architecture of claim 1,
wherein each component of the plurality of components has a component type, and
generating the system reliability comprises:
identifying at least one faulty component designated in the failure scenario;
identifying the component type of the faulty component;
generating a first reliability of a first component type of the faulty component;
generating a second reliability of a second component type of a non-faulty component, based on the connection combination of the first component types and the second component type; and
generating the system reliability based on the first reliability and the second reliability.

4. The method for designing a powertrain system architecture of claim 3,
wherein, when the connection combination is formed by connecting homogeneous components in parallel to implement redundancy of the homogeneous components in the component type, the faulty components are provided as redundant components, and
the first reliability is generated using a reliability calculation based on the number of non-faulty components among the redundant components.

5. The method for designing a powertrain system architecture of claim 1, wherein the risk level data and the severity data are provided for each of a plurality of performance indices, the performance indices are a takeoff distance of the mobility apparatus, a climb gradient of the mobility apparatus, and cruising capability of the mobility apparatus, the cruising capability comprises at least one of a cruising climb gradient and left energy to a specific point, and the risk level comprises a plurality of risk levels classified for each of the performance indices.

6. The method for designing a powertrain system architecture of claim 5,
wherein the allowable failure rate is provided for each of the plurality of performance indices, and
adopting the system architecture comprises adopting the system architecture satisfying all selection conditions of the system reliability for the allowable failure rate for each of the performance indices.

7. The method for designing a powertrain system architecture of claim 1, wherein the allowable failure rate of the system is set for each of a plurality of certification levels, each of the certification levels is classified depending on the number of passengers on board the mobility apparatus, a maximum takeoff weight of the mobility apparatus, and a propulsion scheme for the mobility apparatus.

8. The method for designing a powertrain system architecture of claim 1,
wherein adopting the system architecture comprises:
selecting the system architecture that satisfies a selection condition of the system reliability based on the allowable failure rate; and
adopting the system architecture that satisfies an adoption condition based on the number of connections between the components in the connection combination from the selected system architectures.

9. The method for designing a powertrain system architecture of claim 1, further comprising, prior to generating the available power rate under failure of the system:
receiving input data for the mobility apparatus design; and
sizing the input data to generate a set of the system architectures,
wherein the input data comprises top-level information, mobility apparatus data, and component data,
the top-level information comprises detailed information related to an electric propulsion-based system, the detailed information comprises environment information, market information, operation information, performance information, and mission information, the environment information is related to environmental pollution reduction and noise, the market information comprises the number of passengers of the mobility apparatus, an internal space of the mobility apparatus, a loadable baggage weight, and a baggage space, the operation information comprises a wing span and operational meteorological conditions, the performance information comprises a speed, payload, maximum travel distance, takeoff and landing distances, operational target altitude, and climb gradient of the mobility apparatus, and the mission information comprises a mission plan and mission scenario of the mobility apparatus,
the mobility apparatus data comprises a mobility apparatus configuration and aerodynamic data of the mobility apparatus, and the component data comprises an energy density, power density, and efficiency of components related to the propulsion system of the mobility apparatus.

10. The method for designing a powertrain system architecture of claim 9, wherein the sizing comprises generating a set of the system architectures comprising a combination of the components, in accordance with functional decomposition based on the top-level information, the mobility apparatus data, and the component data.

11. An apparatus for designing a powertrain system architecture for a mobility apparatus based on an allowable failure rate of a system and reliability, the apparatus comprising:
a memory configured to store computer executable instructions; and
at least one processor configured to access the memory and execute the instructions, wherein the instructions comprise:
generating an available power rate under failure of a system based on a failure scenario for a system architecture of a mobility apparatus including a plurality of components according to a failure of components in the system architecture;
generating a system reliability according to the failure scenario based on a failure rate of at least one component and a connection combination between the components of the system architecture;
determining severity data of the system related to the available power rate under failure, based on risk level data indicating a correlation between a risk level and a power reduction rate of the system according to the available power rate under failure; and
determining whether to adopt the system architecture based on an allowable failure rate of the system corresponding to the severity data and the system reliability.

12. The apparatus for designing a powertrain system architecture of claim 11, wherein each component of the plurality of components is allocated to a component type of a plurality of component types, the component type comprises a thrust source configured to generate thrust of the mobility apparatus, a power source configured to transmit power to the thrust source, an energy source configured to supply electrical energy to the power source, and a distribution device configured to manage power between the power source and the energy source, and the failure scenario is based on a failure of the at least one component.

13. The apparatus for designing a powertrain system architecture of claim 11,
wherein each component of the plurality of components has a component type, and
the generation of the system reliability comprises:
identifying at least one faulty component designated in the failure scenario and the component type to which the faulty component belongs;
generating a first reliability of a component type comprising the faulty component and a second reliability of another component type comprising a normal component, based on the connection combination of the component types; and
generating the system reliability based on the first reliability and the second reliability.

14. The apparatus for designing a powertrain system architecture of claim 13,
wherein, when the connection combination is formed by connecting homogeneous components in parallel to implement redundancy of the homogeneous components in the component type, the faulty components are provided as redundant components, and
the first reliability is generated using a reliability calculation process based on the number of normal components excluding the number of normal components among the redundant components.

15. The apparatus for designing a powertrain system architecture of claim 11, wherein the risk level data and the severity data are provided for each of a plurality of performance indices, the performance indices are a takeoff distance of the mobility apparatus, a climb gradient of the mobility apparatus, and cruising capability of the mobility apparatus, the cruising capability comprises at least one of a cruising climb gradient and left energy to a specific point, and the risk level comprises a plurality of risk levels classified for each of the performance indices.

16. The apparatus for designing a powertrain system architecture of claim 15,
wherein the allowable failure rate is provided for each of the plurality of performance indices, and
the determination as to whether to adopt the system architecture comprises adopting the system architecture satisfying all selection conditions of the system reliability for the allowable failure rate for each of the performance indices.

17. The apparatus for designing a powertrain system architecture of claim 11, wherein the allowable failure rate of the system is set for each certification level of a plurality of certification levels classified depending on the number of passengers on board the mobility apparatus, a maximum takeoff weight of the mobility apparatus, and a propulsion scheme for the mobility apparatus.

18. The apparatus for designing a powertrain system architecture of claim 11, wherein the determining of whether to adopt the system architecture comprises:
selecting the system architecture that satisfies a selection condition of the system reliability based on the allowable failure rate; and
adopting the system architecture that satisfies an adoption condition based on the number of connections between the components in the connection combination from the selected system architectures.

19. The apparatus for designing a powertrain system architecture of claim 1,
wherein, prior to generating of the available power rate under failure of the system, the processor is further configured to receive input data for the mobility apparatus design, and sizing the input data to generate a set of the system architectures,
the input data comprises top-level information, mobility apparatus data, and component data,
the top-level information comprises detailed information related to an electric propulsion-based system, the detailed information comprises environment information, market information, operation information, performance information, and mission information, the environment information is related to environmental pollution reduction and noise, the market information comprises the number of passengers of the mobility apparatus, an internal space of the mobility apparatus, a loadable baggage weight, and a baggage space, the operation information comprises a wing span and operational meteorological conditions, the performance information comprises a speed, payload, maximum travel distance, takeoff and landing distances, operational target altitude, and climb gradient of the mobility apparatus, and the mission information comprises a mission plan and mission scenario of the mobility apparatus,
the mobility apparatus data comprises a mobility apparatus configuration and aerodynamic data of the mobility apparatus, and the component data comprises an energy density, power density, and efficiency of components related to the propulsion system of the mobility apparatus.

20. The apparatus for designing a powertrain system architecture of claim 19, wherein sizing comprises generating a set of the system architectures comprising a combination of the components, in accordance with functional decomposition based on the top-level information, the mobility apparatus data, and the component data.
